(19) United States
(12) Patent Application Publication
(10) Pub. No.: US 2017/0352822 A1
(43) Pub. Date: Dec. 7, 2017

(54) PLATINUM BASED OLED EMITTER SHOWING VISIBLE OR NEAR-INFRARED EMISSION

(71) Applicant: National Tsing Hua University, Hsinchu City (TW)

(72) Inventor: Yun Chi, Hsinchu City (TW)

(73) Assignee: National Tsing Hua University, Hsinchu City (TW)

(21) Appl. No.: 15/355,838

(22) Filed: Nov. 18, 2016

(30) Foreign Application Priority Data
Jun. 7, 2016 (TW) 105117900

(51) Int. Cl. H01L 51/00; C07F 15/00; C09K 11/06; H01L 51/50

(52) U.S. Cl. CPC H01L 51/0087; C09K 11/06; C07F 15/0086; C09K 2211/185; H01L 51/5012; C09K 2211/1044

(57) ABSTRACT

A platinum complex, an OLED using the platinum complex, and an apparatus emitting visible light or near-IR light are provided. The platinum complex has a structure represented by formula (I):

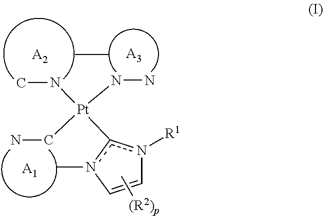

wherein A1 to A3 are each independently a six-membered ring or a five-membered ring; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl, or substituted or unsubstituted C₁-C₆ alkoxy; p is an integer of 1 to 2; when p is equal to 2, two R²'s can be joined to form a C₃-C₈ aromatic ring; and a first chelating ligand having A1 and a carbene fragment has a minus one formal charge and a second chelating ligand having A2 and A3 has a minus one formal charge.

### CROSS-REFERENCE TO RELATED APPLICATION

This application claims the priority benefit of Taiwan application serial no. 105117900, filed on Jun. 7, 2016. The entirety of the above-mentioned patent application is hereby incorporated by reference herein and made a part of this specification.

### BACKGROUND OF THE INVENTION

### Field of the Invention

The invention relates to a metal complex, and more particularly, to a platinum complex and an application thereof.

### Description of Related Art

The organic-light emitting diode (OLED) device has received much attention in the display industry, in particular the flat panel display industry since the OLED devices can be operated under low driving voltage and can generate high luminous efficiency.

To develop various new light-emitting devices having an emission range covering the visible region and the near-infrared region, the development of various colored light-emitting materials having high stability and high emission efficiency is the main object of current OLED research. The existing tetracoordinated platinum complex has suitable emission characteristics, but the rigidity and stability thereof are still sometimes insufficient.

### SUMMARY OF THE INVENTION

The invention provides a platinum complex having structural stability and excellent luminous efficiency.

The invention also provides an OLED including the platinum complex and an apparatus capable of emitting visible light or near-IR light.

The platinum complex of the invention has a structure represented by general formula (I):

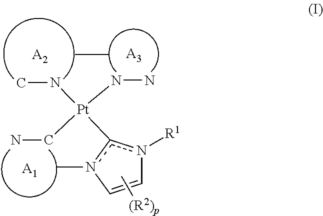

wherein A1 to A3 are each independently a six-membered ring or a five-membered ring; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl, or substituted or unsubstituted C₁-C₆ alkoxy; p is an integer of 1 to 2; when p is equal to 2, two R²'s can be joined to form a C₃-C₈ aromatic ring; and a first chelating ligand having A1 and a carbene functional group has a minus one formal charge and a second chelating ligand having both A2 and A3 has a minus one formal charge.

In an embodiment of the invention, the platinum complex has a structure represented by general formula (I-1):

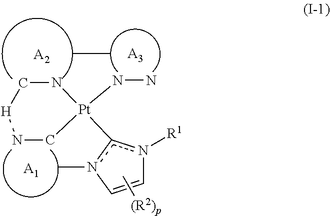

wherein an inter-ligand hydrogen bond exists between the first chelating ligand and the second chelating ligand.

In an embodiment of the invention, the platinum complex has a structure represented by general formula (IA):

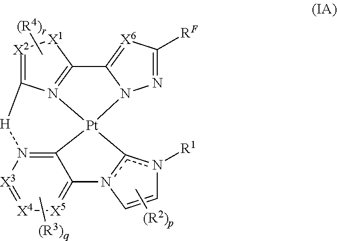

wherein X¹ is oxygen, sulfur, or nitrogen; X² to X⁶ are each independently carbon or nitrogen; R^{F} is an electron withdrawing group; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl or substituted or unsubstituted C₁-C₆ alkoxy; p is an integer of 1 to 2; each R³ is independently hydrogen, substituted or unsubstituted C₁-C₁₂ alkyl, substituted or unsubstituted C₁-C₆ alkoxy, or —CₘF₂ₘ₊₁, m is an integer of 0 to 3; q is an integer of 0 to 3; each R⁴ is independently hydrogen, fluorine, substituted or unsubstituted C₁-C₁₂ alkyl, substituted or unsubstituted C₆-C₁₂ aryl, or substituted or unsubstituted C₁-C₆ alkoxy; r is an integer of 0 to 2; when p is equal to 2, two R²'s can be joined to form a C₃-C₈ aromatic ring; when q is equal to or greater than 2, two or more R³'s can be joined to form a C₃-C₈ aromatic ring; and when r is equal to 2, two R⁴'s can be joined to form a C₃-C₈ aromatic ring.

In an embodiment of the invention, the platinum complex has a structure represented by general formula (IB):

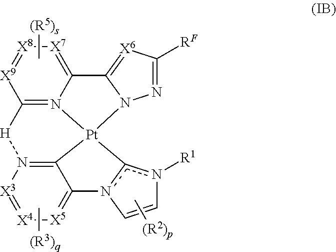

wherein X³ to X⁹ are each independently carbon or nitrogen; R^{F} is an electron withdrawing group; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl or substituted or unsubstituted C₁-C₆ alkoxy; p is an integer of 1 to 2; each R³ is independently hydrogen, substituted or unsubstituted C₁-C₁₂ alkyl, substituted or unsubstituted C₁-C₆ alkoxy, or —CₘF₂ₘ₊₁, in is an integer of 0 to 3; q is an integer of 0 to 3; each R⁵ is independently hydrogen, fluorine, substituted or unsubstituted C₁-C₁₂ alkyl, or substituted or unsubstituted C₁-C₆ alkoxy; s is an integer of 0 to 3; when p is equal to 2, two R²'s can be joined to form a C₃-C₈ aromatic ring; when q is equal to or greater than 2, two or more R³'s can be joined to form a C₃-C₈ aromatic ring; and when s is equal to or greater than 2, two or more R⁵'s can be joined to form a C₃-C₈ aromatic ring.

A hydrogen bond exists between two chelating ligands of the platinum complex of the invention, and therefore the bonding strength of the chelating ligands and a central platinum metal can be increased, such that the structure of the platinum complex of the invention is more stable. The total negative charge of two chelating ligands of the platinum complex of the invention is the same as the positive charge of the central platinum metal ion, so a neutral platinum complex can be formed. A neutral complex generally has better volatility, and therefore a multilayer OLED light-emitting device can be formed using an evaporation method, and the luminous efficiency thereof can be improved. Moreover, the platinum complex of the invention has two N—Pt coordination bonds and two C—Pt coordination bonds. Since the bond energy of C—Pt bond is greater than the bond energy of N—Pt interaction, by increasing the relative number of C—Pt bonds, the overall bonding strength between the chelating ligands and the central metal atom can be increased. Accordingly, the energy level of metal-centered dd excited states can be increased, such that influence on the lowest energy excited state from the dd excited states can be reduced, and non-radiative quenching can be reduced as well. As a result, the luminous efficiency of the complex can be increased. Moreover, in the platinum complex of the invention, the ring structures of A1 and A3 contain nitrogen atoms with high electronegativity, and such nitrogen atoms are beneficial to increase the stacking effect between molecules, reduce the Pt—Pt intermolecular distance, and induce metal-metal-to-ligand charge transfer transition (MMLCT) within the solid state. Therefore, shorter luminous half-life and better emission efficiency of the complex of the invention are provided.

It should be understood, however, that this Summary may not contain all of the aspects and embodiments of the present disclosure, is not meant to be limiting or restrictive in any manner, and that the disclosure as disclosed herein is and will be understood by those of ordinary skill in the art to encompass obvious improvements and modifications thereto.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows the absorption spectrum and the emission spectrum of each of compounds (IA-1), (IA-2), (IA-4), (IA-5), and (IA-6) synthesized in examples 1 to 5 of the invention.

FIG. 2 shows the absorption spectrum and the emission spectrum of each of compounds (IB-1), (IB-2), (IB-4), and (IB-5) synthesized in examples 6 to 9 of the invention.

FIG. 3 shows the absorption spectrum and the emission spectrum of each of compounds (IB-8), (IB-9), (IB-10), and (IB-11) synthesized in examples 10 to 13 of the invention.

### DESCRIPTION OF THE EMBODIMENTS

In the following, embodiments are provided to further describe the invention, but the embodiments are only exemplary and are not intended to limit the scope of the invention.

The platinum complex of the invention has a structure represented by general formula (I):

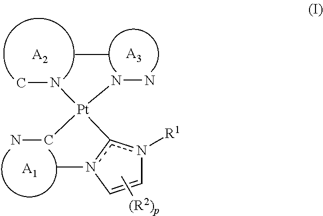

wherein A1 to A3 are each independently a six-membered ring or a five-membered ring; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl, or substituted or unsubstituted C₁-C₆ alkoxy; p is an integer of 1 to 2; when p is equal to 2, two R²'s can be joined to form a C₃-C₈ aromatic ring; and a first chelating ligand having A1 and a carbene fragment (or a carbene functional group) has a minus one formal charge (or valence) and a second chelating ligand having both A2 and A3 has a minus one formal charge (or valence).

Since the total negative charge of two chelating ligands of the platinum complex of the invention is the same as the positive charge of the central platinum metal ion, a neutral platinum complex can be formed. A neutral complex generally has better volatility, and therefore a multilayer OLED light-emitting device can be formed using an evaporation method, and the luminous efficiency thereof can be improved.

In an embodiment, the platinum complex of the invention has a structure represented by general formula (I-1):

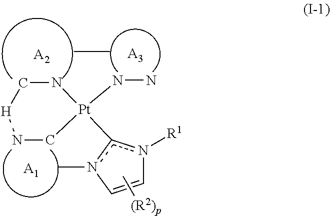

wherein an inter-ligand hydrogen bond exists between the first chelating ligand and the second chelating ligand.

A hydrogen bond exists between two chelating ligands of the platinum complex of the invention, and therefore the bonding strength of the chelating ligands and the central platinum metal can be increased, such that the structure of the platinum complex of the invention is more stable.

In an embodiment, when A1 is a six-membered ring, A2 is a five-membered ring, and A3 is a five-membered ring, the platinum complex of the invention has a structure represented by general formula (IA):

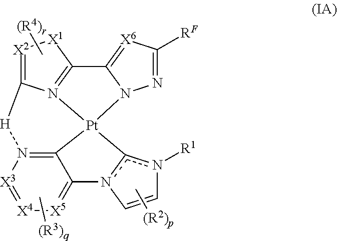

wherein X¹ is carbon, oxygen, sulfur, or nitrogen; X² to X⁶ are each independently carbon or nitrogen; R^{F} is an electron withdrawing group; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl or substituted or unsubstituted C₁-C₆ alkoxy; p is an integer of 1 to 2; each R³ is independently hydrogen, substituted or unsubstituted C₁-C₁₂ alkyl, substituted or unsubstituted C₁-C₆ alkoxy, or —CₘF₂ₘ₊₁, m is an integer of 0 to 3; q is an integer of 0 to 3; each R⁴ is independently hydrogen, fluorine, substituted or unsubstituted C₁-C₁₂ alkyl, substituted or unsubstituted C₆-C₁₂ aryl, or substituted or unsubstituted C₁-C₆ alkoxy; r is an integer of 0 to 2; when p is equal to 2, two R²'s can be joined to form a C₃-C₈ aromatic ring; when q is equal to or greater than 2, two or more R³'s can be joined to form a C₃-C₈ aromatic ring; and when r is equal to 2, two R⁴'s can be joined to form a C₃-C₈ aromatic ring.

In an embodiment, X³ and X⁵ are both carbon, wherein q is 2, two R³'s are respectively bonded to X³ and X⁵, r is 1, and R⁴ is bonded to X¹.

In an embodiment, R^{F} includes —CₘF₂ₘ₊₁, and m is an integer of 0 to 3.

In an embodiment, the platinum complex of the invention has a structure represented by one of formula (IA-1) to formula (IA-8):

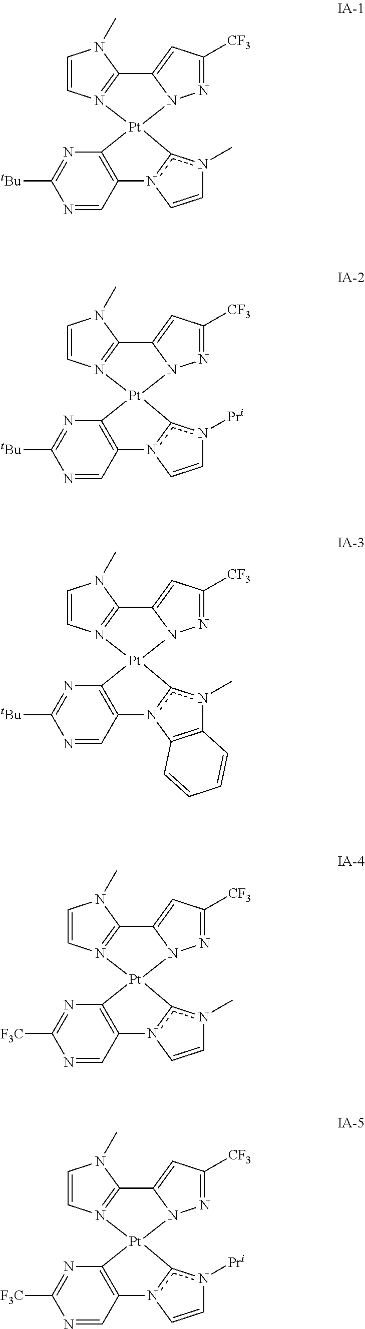

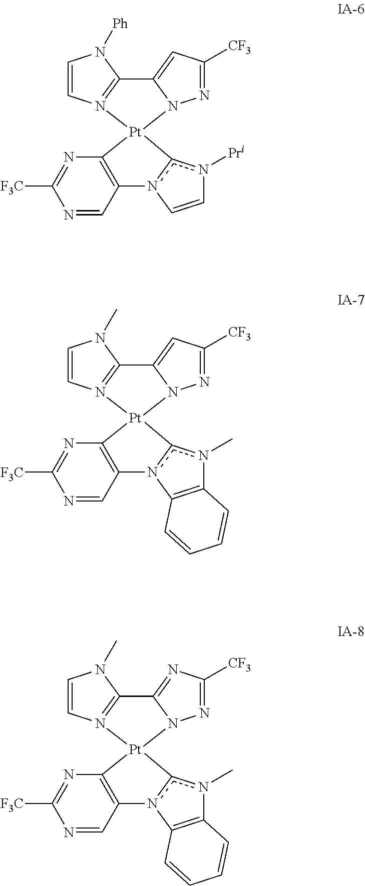

In another embodiment, when A1 is a six-membered ring, A2 is a six-membered ring, and A3 is a five-membered ring, the platinum complex of the invention has a structure represented by general formula (IB):

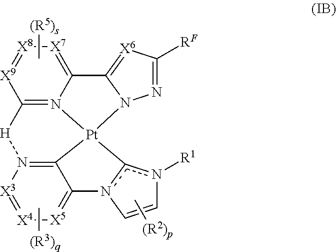

wherein X³ to X⁹ are each independently carbon or nitrogen; R^{F} is an electron withdrawing group; R¹ is substituted or unsubstituted C₁-C₁₂ alkyl or substituted or unsubstituted C₆-C₁₂ aryl; each R² is independently hydrogen, substituted or unsubstituted C₁-C₁₂ alkyl or substituted or unsubstituted C₁-C₆ alkoxy; p is an integer of 1 to 2; each R³ is independently hydrogen, substituted or unsubstituted C₁-C₁₂ alkyl, substituted or unsubstituted C₁-C₆ alkoxy, or —CₘF₂ₘ₊₁, m is an integer of 0 to 3; q is an integer of 0 to 3; each R⁵ is independently hydrogen, fluorine, substituted or unsubstituted C₁-C₁₂ alkyl, or substituted or unsubstituted C₁-C₆ alkoxy; s is an integer of 0 to 3; when p is equal to 2, two R²'s can be joined to form a C₃-C₈ aromatic ring; when q is equal to or greater than 2, two or more R³'s can be joined to form a C₃-C₈ aromatic ring; and when s is equal to or greater than 2, two or more R⁵'s can be joined to form a C₃-C₈ aromatic ring.

As shown by general formula (I-1), general formula (IA), and general formula (IB), a hydrogen bond exists between two chelating ligands of the platinum complex of the invention. For example, a hydrogen bond is present at the left side of the structures shown in general formula (I-1), general formula (IA), and general formula (IB). Since a hydrogen bond exists between two chelating ligands of the platinum complex of the invention, the square planar structure of the platinum complex of the invention is more stable. A stable structure allows better intermolecular stacking of the platinum complex of the invention, such that a longer emission wavelength can be more readily achieved.

The aromatic ring can include an aromatic hydrocarbon ring or an aromatic heterocyclic ring. Specific examples of the aromatic ring include a phenyl ring, a pyridine ring, a pyrazine ring, a pyrimidine ring, a pyridazine ring, a triazine ring, a pyrrole ring, a furan ring, a thiophene ring, a selenophene ring, a tellurophene ring, an imidazole ring, a thiazole ring, a selenazole ring, a tellurazole ring, a thiadiazole ring, an oxadiazole ring, and a pyrazole ring.

In an embodiment, the platinum complex of the invention has a structure represented by one of formula (IB-1) to formula (IB-15):

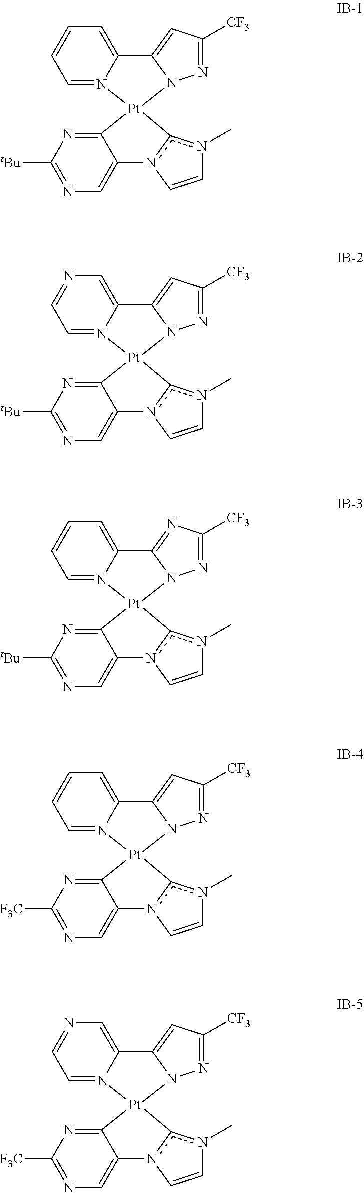

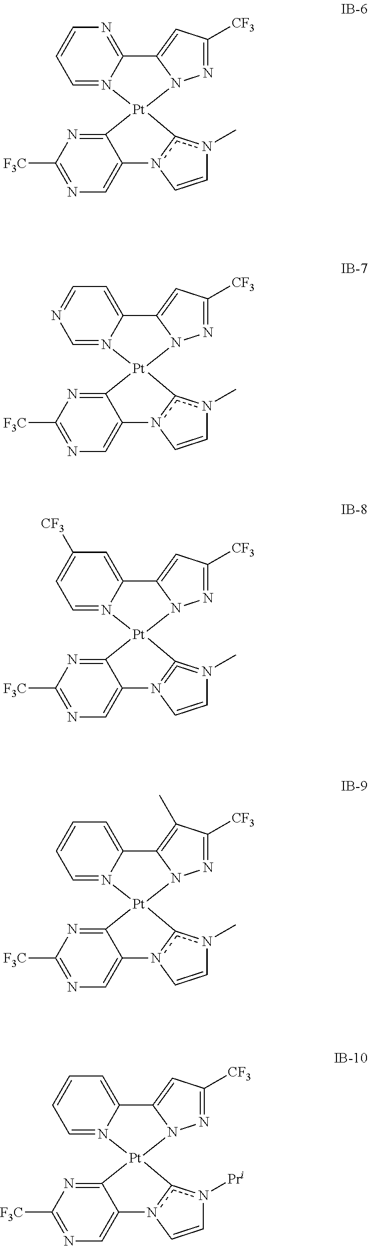

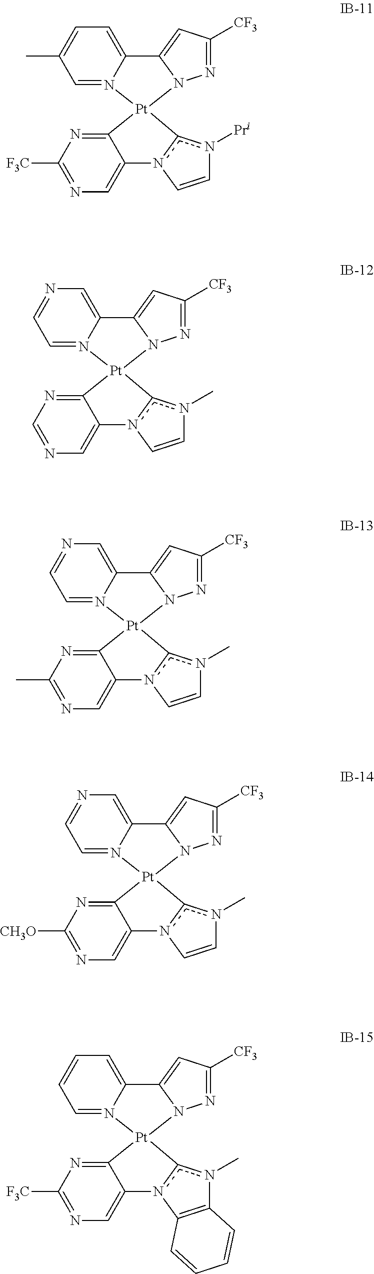

In an embodiment, the platinum complex of the invention has an emission wavelength of about 450 nm and 750 nm, so the application thereof is broad. More specifically, when the emission wavelength of the platinum complex of the invention is in the visible light range, such platinum complex can be applied in the organic light-emitting diode (OLED) field. When the emission wavelength of the platinum complex of the invention is greater than 700 nm and falls within the near-infrared (IR) range, such platinum complex can be applied in the military or medical field to provide a light source invisible to the naked eye or a light source capable of penetrating the human body or animal tissue.

In an embodiment, the invention provides an apparatus emitting visible light or near-IR light and including the platinum complex.

In an embodiment, the invention provides an OLED including two electrodes and a light-emitting layer disposed between the two electrodes, and the light-emitting layer contains the platinum complex. The platinum complex can be used as a dopant for a host material of the light-emitting layer. The material of each of the two electrodes can be selected from materials commonly used in the field, and other functional layers (such as an electron-transport layer, a hole-injection layer, a hole-transport layer, a hole-blocking layer or the like) can also be disposed between each of the electrodes and the light-emitting layer via a known technique in the art. The OLED can be manufactured on a flat substrate, such as conductive glass or a plastic substrate.

### [Forming Method of Platinum Complex]

### Synthesis of Chelating Ligand Precursor Having Carbene Structure

In the invention, a chelating ligand having a carbene structure is used as the first chelating ligand of the platinum complex. In an embodiment, the precursor of the first chelating ligand of the invention is obtained via the following method:

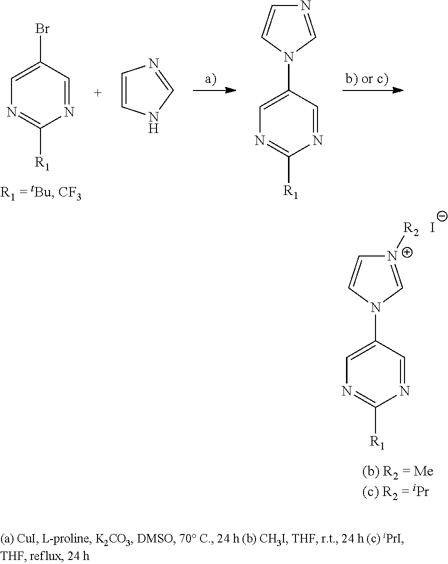

The precursor of the first chelating ligand of the invention can be prepared by adopting suitable reactants and reaction conditions based on changes of each chelating ligand, and the reaction preparation method can be modified based on a known technique in the art.

In the following, N-(2-tert-butylpyrimidin-5-yl)-N′-methylimidazolium iodide is used as an example of the first chelating ligand of the invention, and the specific synthetic steps thereof are as follows.

First, the synthesis of N-(2-tert-butylpyrimidin-5-yl)imidazole (shown below) was performed.

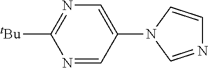 [SMILES: CC(C)(C)c1ncc(-n2ccnc2)cn1]

The synthetic steps are as follows:

2-tert-butyl-5-bromopyrimidine (324 mg, 1.51 mmol), imidazole (68 mg, 1.66 mmol), copper iodide (57 mg, 0.30 mmol), L-proline (69 mg, 0.60 mmol), potassium carbonate (833 mg, 6.04 mmol), and dimethyl sulfoxide (5 mL) were placed in a sealed tube to react at 70° C. for 24 hours. The reaction mixture was cooled to room temperature and stratified in water and ethyl acetate. The organic layers were separated and the aqueous layer was extracted using ethyl acetate. The organic layers were combined, washed with salt water, then dried using anhydrous sodium sulfate, and then concentrated under reduced pressure. The residue was separated using column chromatography (silicone, ethyl acetate/hexane=1:1) to obtain a white solid (198 mg, 0.98 mmol, yield: 65%).

Spectral data of N-(2-tert-butylpyrimidin-5-yl)imidazole: ¹H NMR (400 MHz, CDCl₃, 298K): δ 8.68 (s, 2H), 7.76 (s, 1H), 7.19 (d, J=4.0 Hz, 1H), 7.17 (d, J=4.0 Hz, 1H), 1.32 (s, 9H). MS (EI) observed (actual): m/z 202 (202) [M⁺].

Then, the synthesis of N-(2-tert-butylpyrimidin-5-yl)-N′-methylimidazolium iodide (shown below) was performed.

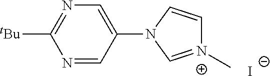 [SMILES: C[n+]1ccn(-c2cnc(C(C)(C)C)nc2)c1 ; [I-]]

The synthetic steps are as follows:

N-(2-tert-butylpyrimidin-5-yl)imidazole (1.63 g, 8.0 mmol) and iodomethane (2.6 mL, 40.6 mmol) were dissolved in tetrahydrofuran (5 mL), the mixture was stirred at room temperature for 24 hours, the precipitate was filtered and washed with tetrahydrofuran, and then dried under vacuum to obtain N-(2-tert-butylpyrimidin-5-yl)-N′-methylimidazolium iodide (1.87 g, 5.43 mmol) with a yield of 67%.

Spectral data of N-(2-tert-butylpyrimidin-5-yl)-N′-methylimidazolium iodide: ¹H NMR (400 MHz, CDCl₃, 298K): δ 10.52 (s, 1H), 9.20 (s, 2H), 7.77 (d, J=8.0 Hz, 1H), 7.73 (d, J=8.0 Hz, 1H), 4.27 (s, 3H), 1.39 (s, 9H). MS (EI) observed (actual): m/z 202 (344) [M-I—CH₃⁺].

Another first chelating ligand precursor includes:

N-(2-tert-butylpyrimidin-5-yl)-N′-isopropylimidazolium iodide (shown below)

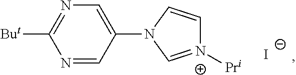

or

N-(2-trifluoromethylpyrimidin-5-yl)-N′-isopropylimidazolium iodide (shown below)

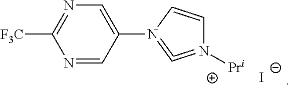

The synthesis method of each of the above-mentioned first chelating ligand precursor is similar to that of N-(2-tert-butylpyrimidin-5-yl)-N′-methylimidazolium iodide, and those having ordinary skill in the art can select suitable reactants and reaction conditions for the preparation based on the changes of each first chelating ligand precursor, and the reaction preparation method can be modified based on a known technique in the art, and are therefore not repeated herein.

### Synthesis of Platinum Complex

The platinum complex of the invention is obtained via, for instance, the following method:

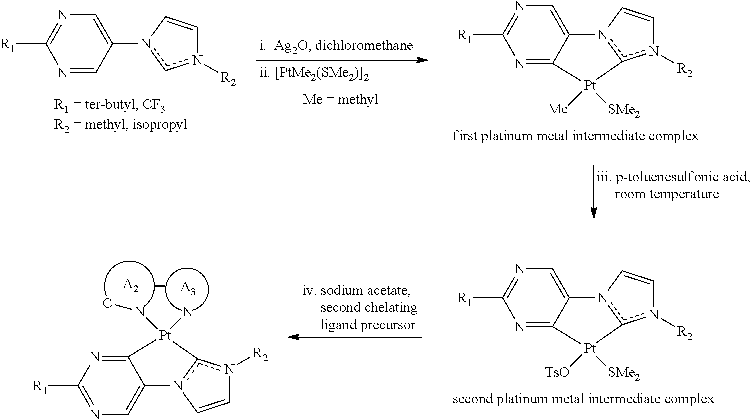

The specific method includes the following steps. The first chelating ligand precursor and silver oxide are mixed in a dichloromethane suspension to obtain carbene silver salt of the first chelating ligand precursor. Thereafter, the carbene silver salt of the first chelating ligand precursor and a platinum source are mixed to obtain a first platinum metal intermediate complex. A suitable amount of p-toluenesulfonic acid is then added to remove one methyl group so as to obtain a second platinum metal intermediate complex. Afterwards, the second chelating ligand precursor and other required reagents are added and the mixture is reacted at low temperature to obtain the platinum metal complex of the invention. The second chelating ligand precursor of the invention is, for instance, a chelating ligand precursor having a nitrogen-containing heterocyclic ring. The platinum complex of the invention can be prepared by adopting suitable reactants and reaction conditions based on changes of each of the chelating ligands, and the reaction preparation method can be modified based on a known technique in the art.

### EXAMPLES

In the following, several examples are provided to further describe the invention, but the examples are only exemplary and are not intended to limit the scope of the invention. The platinum complexes represented by formulas (IA-1), (IA-2), (IA-3) . . . , or (IB-1), (IB-2), (IB-3) . . . are abbreviated as compounds (IA-1), (IA-2), (IA-3) . . . , or (IB-1), (IB-2), (IB-3) . . . hereinafter. The abbreviation also applies to platinum complexes represented by other chemical structures in the following.

### Example 1

Preparation of Compound (IA-1):

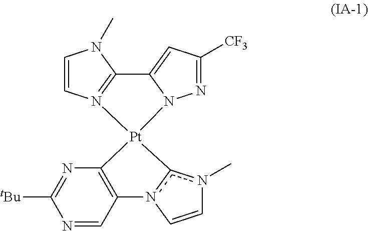

(1-methyl-3-(2-tert-butylpyrimidin-5-yl) imidazol-2-ylidine) silver iodide (126 mg, 0.28 mmol), [PtMe₂(SMe₂)]₂ (80 mg, 0.14 mmol), and tetrahydrofuran (10 mL) were added in a 50 mL round-bottom flask. The reaction mixture was stirred at room temperature for 1 hour, and the precipitate was filtered. The resulting filtrate was stirred at 55° C. for 2 hours then cooled to room temperature, and then a tetrahydrofuran (2 mL) solution of p-toluenesulfonic acid (53 mg, 0.28 mmol) was added thereto. The mixture was stirred for 30 minutes. The reaction mixture was cooled to −40° C., then sodium acetate (23 mg, 0.28 mmol) and a methanol (3 mL) solution of 5-(1-methyl-1H-imidazol-2-yl)-3-(trifluoromethyl)-1H-pyrazole (60 mg, 0.28 mmol) were added. The mixture was reacted at −40° C. for 2 hours. After the reaction was completed, the reaction mixture was returned to room temperature, and then the solvent was removed and the residue was extracted using dichloromethane. The organic layers were combined, washed with water, dried with anhydrous sodium sulfate, filtered and evaporated to dryness, and the residue was then purified with column chromatography (silicone, ethyl acetate:n-hexane=1:3) to obtain a green powder with a yield of 45%.

Spectral data of compound (IA-1): ¹H NMR (400 MHz, DMSO-d₆, 298K): δ 8.77 (d, J=1.4 Hz, 1H), 8.45 (s, 1H), 8.07 (d, J=2.0 Hz, 1H), 7.50 (d, J=1.4 Hz, 1H), 7.48 (d, J=2.0 Hz, 1H), 7.04 (s, 1H), 4.50 (s, 3H), 3.95 (s, 3H), 1.44 (s, 9H). ¹⁹F NMR (376 MHz, DMSO-d₆, 298K): δ −58.87 (s, 3F). MS (FAB, ¹⁹⁵Pt): observed (actual) m/z 625 (625) [M⁺].

### Example 2

Preparation of Compound (IA-2):

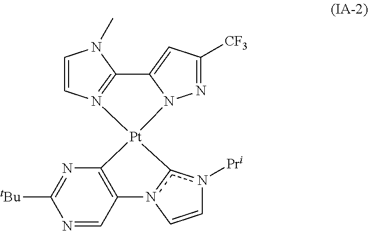

Except that the reactant (1-methyl-3-(2-tert-butylpyrimidin-5-yl)imidazol-2-ylidine) silver iodide was replaced with (1-isopropyl-3-(2-tert-butylpyrimidin-5-yl)imidazol-2-ylidine) silver iodide, the synthetic protocols of compound (IA-2) were similar to the synthetic procedures of compound (IA-1). After the reaction was completed, the solvent was removed and the residue was extracted using dichloromethane. The organic layers were combined, washed with water, dried with anhydrous sodium sulfate and filtered, and then purified with column chromatography (silicone, ethyl acetate:n-hexane=1:3) to obtain a green solid with a yield of 42%.

Spectral data of compound (IA-2): ¹H NMR (400 MHz, CDCl₃, 298K): δ 8.95 (d, J=1.6 Hz, 1H), 8.07 (s, 1H), 7.34 (d, J=2.1 Hz, 1H), 7.10 (d, J=2.1 Hz, 1H), 6.99 (septet, J=6.6 Hz, 1H), 6.93 (d, J=1.6 Hz, 1H), 6.64 (s, 1H), 3.87 (s, 3H), 1.51 (d, J=6.6 Hz, 6H). ¹⁹F NMR (376 MHz, CDCl₃, 298K): δ −60.37. MS (FAB, ¹⁹⁵Pt): observed (actual) m/z 653 (653) [M⁺].

### Example 3

Preparation of Compound (IA-4):

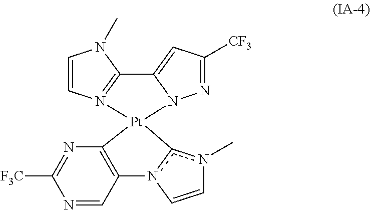

Except that the reactant (1-methyl-3-(2-tert-butylpyrimidin-5-yl)imidazol-2-ylidine) silver iodide was replaced with (1-methyl-3-(2-trifluoromethylpyrimidin-5-yl)imidazol-2-ylidine) silver iodide, the synthetic steps of compound (IA-4) were similar to the synthetic steps of compound (IA-1). Since the solubility of the product was poor, water was added to the reaction mixture after the reaction was completed. The mixture was filtered, and the precipitate was washed with ether for several times. The crude product was dried under vacuum and sublimed under the condition of 270° C. to obtain an orange solid with a yield of 56%.

Spectral data of compound (IA-4): ¹H NMR (400 MHz, acetone-d₆, 298K): δ 8.72 (d, J=1.7 Hz, 1H), 8.64 (s, 1H), 8.07 (d, J=2.1 Hz, 1H), 7.49 (d, J=2.1 Hz, 1H), 7.40 (d, J=1.7 Hz, 1H), 6.94 (s, 1H), 4.66 (s, 3H), 4.08 (s, 3H). ¹⁹F NMR (376 MHz, acetone-d₆, 298K): δ −61.02 (s, 3F), −69.97 (s, 3F). MS (FAB, ¹⁹⁵Pt): observed (actual) m/z 637 (637) [M⁺].

### Example 4

Preparation of Compound (IA-5):

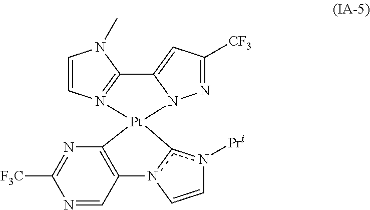

Except that the reactant (1-methyl-3-(2-tert-butylpyrimidin-5-yl)imidazol-2-ylidine)silver iodide was replaced with (1-isopropyl-3-(2-trifluoromethylpyrimidin-5-yl)imidazol-2-ylidine)silver iodide, the synthetic steps of compound (IA-5) were similar to the synthetic steps of compound (IA-1). After the reaction was completed, the solvent was removed and the residue was dissolved in dichloromethane then washed with water. The organic layers were dried using anhydrous sodium sulfate, filtered and evaporated to dryness, and the residue was purified with column chromatography (silicone, ethyl acetate/n-hexane=1:1) to obtain a green solid with a yield of 47%.

Spectral data of compound (IA-5): ¹H NMR (400 MHz, CDCl₃, 298K): δ 8.66 (d, J=1.5 Hz, 1H), 8.09 (s, 1H), 7.36 (d, J=2.1 Hz, 1H), 7.14 (d, J=2.1 Hz, 1H), 6.97 (septet, J=6.7 Hz, 1H), 6.90 (d, J=1.5 Hz, 1H), 6.59 (s, 1H), 3.85 (s, 3H), 1.50 (d, J=6.7 Hz, 6H). ¹⁹F NMR (376 MHz, CDCl₃, 298K): δ −60.87 (s, 3F), −69.46 (s, 3F). MS (FAB, ¹⁹⁵Pt): observed (actual) m/z 665 (665) [M⁺].

### Example 5

Preparation of Compound (IA-6):

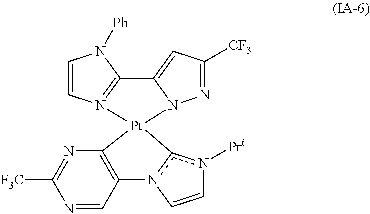

Except that the reactant (1-methyl-3-(2-tert-butylpyrimidin-5-yl)imidazol-2-ylidine) silver iodide was replaced with (1-isopropyl-3-(2-trifluoromethylpyrimidin-5-yl)imidazol-2-ylidine) silver iodide and the reactant 5-(1-methyl-1H-imidazol-2-yl)-3-(trifluoromethyl)-1H-pyrazole was replaced with 5-(1-phenyl-1H-imidazol-2-yl)-3-(trifluoromethyl)-1H-pyrazole, the synthesis of compound (IA-6) were similar to the synthetic steps of compound (IA-1). After the reaction was completed, the solvent was removed and the residue was extracted using dichloromethane. The organic layers were combined, washed with water, dried with anhydrous sodium sulfate, filtered and evaporated to dryness, and the residue was then purified with column chromatography (silicone, ethyl acetate:n-hexane=1:3) to obtain a yellow solid with a yield of 42%.

Spectral data of compound (IA-6): ¹H NMR (400 MHz, CDCl₃, 298K): δ 8.94 (d, J=1.7 Hz, 1H), 8.21 (s, 1H), 7.60-7.59 (m, 4H), 7.52-7.40 (m, 2H), 7.19 (d, J=2.3 Hz, 1H), 7.16 (d, J=1.7 Hz, 1H), 7.09-7.01 (septet, J=6.7 Hz, 1H), 5.88 (s, 1H), 2.15 (dd, J=6.7 Hz, 6H). ¹⁹F NMR (376 MHz, CDCl₃, 298K) δ −60.94 (s, 3F), −69.45 (s, 3F). MS (FAB, ¹⁹⁵Pt): observed (actual) m/z 727 (727) [M⁺].

### Example 6

Preparation of Compound (IB-1):

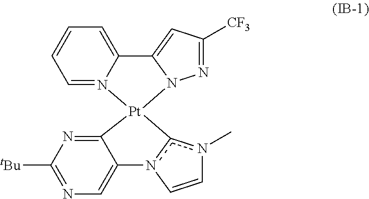

Except that the reactant 5-(1-methyl-1H-imidazol-2-yl)-3-(trifluoromethyl)-1H-pyrazole was replaced with 2-(3-(trifluoromethyl)-1H-pyrazol-5-yl)pyridine, the synthesis of compound (IB-1) followed the similar synthetic steps of compound (IA-1). After the reaction was completed, the solvent was removed, and the product was purified using column chromatography (silicone, ethyl acetate:n-hexane=1:3) to obtain a yellow solid with a yield of 63%.

Spectral data of compound (IB-1): ¹H NMR (400 MHz, CDCl₃, 298K): δ 11.38 (d, J=5.3 Hz, 1H), 8.10 (s, 1H), 7.91 (dd, J=7.7, 6.7 Hz, 1H), 7.63 (d, J=7.7 Hz, 1H), 7.36 (dd, J=6.7, 5.3 Hz, 1H), 7.33 (d, J=2.0 Hz, 1H), 6.96 (d, J=2.0 Hz, 1H), 6.82 (s, 1H), 4.60 (s, 3H), 1.55 (s, 9H). ¹⁹F NMR (376 MHz, CDCl₃, 298K): δ −61.15 (s, 3F). MS (FAB, ¹⁹⁵Pt): observed (actual) m/z 622 (622) [M⁺].

### Example 7

Preparation of Compound (IB-2):

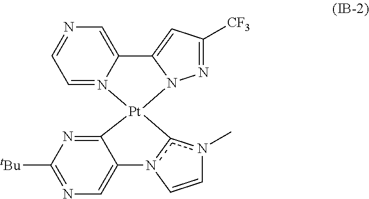

Except that the reactant 5-(1-methyl-1H-imidazol-2-yl)-3-(trifluoromethyl)-1H-pyrazole was replaced with 2-(3-(trifluoromethyl)-1H-pyrazol-5-yl)pyrazine, the synthesis of compound (IB-2) followed the similar synthetic steps of compound (IA-1). After the reaction was completed, the solvent was removed. The residue was purified using column chromatography (silicone, ethyl acetate/hexane=1:2) to obtain a dark red solid with a yield of 43%.

Spectral data of compound (IB-2): ¹H NMR (400 MHz, acetone-d₆, 298K): δ 11.47 (dd, J=1.3, 3.3 Hz, 1H), 9.33 (d, J=1.3 Hz, 1H), 8.82 (d, J=3.3 Hz, 1H), 8.47 (s, 1H), 7.98 (d, J=2.1 Hz, 1H), 7.45 (d, J=2.1 Hz, 1H), 7.26 (s, 1H), 4.60 (s, 3H), 1.51 (s, 9H). ¹⁹F NMR (376 MHz, acetone-d₆, 298K): δ −61.02 (s, 3F). MS (FAB, ¹⁹⁵Pt): observed (actual) m/z 623 (623) [M⁺].

### Example 8

Preparation of Compound (IB-4):

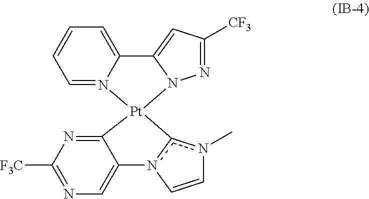

Except that the reactant (1-methyl-3-(2-tert-butylpyrimidin-5-yl)imidazol-2-ylidine) silver iodide was replaced with (1-methyl-3-(2-trifluoromethylpyrimidin-5-yl)imidazol-2-ylidine) silver iodide and the reactant 5-(1-methyl-1H-imidazol-2-yl)-3-(trifluoromethyl)-1H-pyrazole was replaced with 2-(3-(trifluoromethyl)-1H-pyrazol-5-yl)pyridine, the synthesis of compound (IB-4) followed the similar synthetic steps of compound (IA-1). Since the solubility of the product was poor, water was added to the reaction mixture and filtering was performed after the reaction was completed. The resulting precipitate was repeatedly washed with ether. The crude product was dried under vacuum and sublimed under the condition of 270° C. to obtain a red solid with a yield of 43%.

Spectral data of compound (IB-4): ¹H NMR (400 MHz, DMSO-d₆, 298K): δ 10.65 (d, J=5.4 Hz, 1H), 8.63 (s, 1H), 8.12-8.10 (dd, J=1.3, 7.6 Hz, 1H), 8.08 (d, J=2.0 Hz, 1H), 7.92 (d, J=7.6 Hz, 1H), 7.46 (d, J=2.0 Hz, 1H), 7.38 (dd, J=1.2, 5.4 Hz, 1H), 7.11 (s, 1H), 4.35 (s, 3H). ¹⁹F NMR (376 MHz, DMSO-d₆, 298K): δ −59.31 (s, 3F), −68.23 (s, 3F). MS (FAB, ¹⁹⁵Pt): observed (actual) m/z 634 (634) [M⁺].

### Example 9

Preparation of Compound (IB-5):

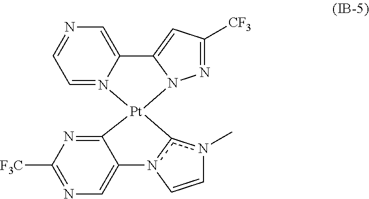

Except that the reactant (1-methyl-3-(2-tert-butylpyrimidin-5-yl)imidazol-2-ylidine) silver iodide was replaced with (1-methyl-3-(2-trifluoromethylpyrimidin-5-yl)imidazol-2-ylidine)silver iodide and the reactant 5-(1-methyl-1H-imidazol-2-yl)-3-(trifluoromethyl)-1H-pyrazole was replaced with 2-(3-(trifluoromethyl)-1H-pyrazol-5-yl)pyrazine, the synthesis of compound (IB-5) followed the similar synthetic steps of compound (IA-1). Since the solubility of the product was poor, water was added to the reaction solution after the reaction was completed and filtering was performed. The precipitate was washed with ether for several times. The crude product was dried under vacuum and sublimed at 270° C. to obtain an orange solid with a yield of 40%.

Spectral data of compound (IB-5): ¹H NMR (400 MHz, DMSO-d₆, 298K): δ 10.42 (d, J=3.2 Hz, 1H), 9.09 (s, 1H), 8.49 (d, J=3.2 Hz, 1H), 8.47 (s, 1H), 7.93 (d, J=1.9 Hz, 1H), 7.31 (d, J=1.9 Hz, 1H), 7.02 (s, 1H), 4.09 (s, 3H). ¹⁹F NMR (376 MHz, DMSO-d₆, 298K): δ −59.52 (s, 3F), −68.19 (s, 3F). MS (FAB): observed (actual) m/z 635 (635) [M⁺].

### Example 10

Preparation of Compound (IB-8):

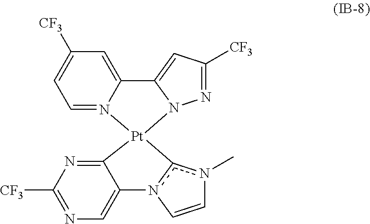

Except that the reactant (1-methyl-3-(2-tert-butylpyrimidin-5-yl)imidazol-2-ylidine) silver iodide was replaced with (1-methyl-3-(2-trifluoromethylpyrimidin-5-yl)imidazol-2-ylidine)silver iodide and the reactant 5-(1-methyl-1H-imidazol-2-yl)-3-(trifluoromethyl)-1H-pyrazole was replaced with 4-(trifluoromethyl)-2-(3-(trifluoromethyl)-1H-pyrazol-5-yl)pyridine, the synthesis of compound (IB-8) followed the similar synthetic steps of compound (IA-1). Since the solubility of the product was poor, water was added to the reaction mixture and the mixture was filtered. The precipitate was washed with ether several times. The crude product was dried under vacuum and sublimed at 270° C. to obtain a dark red solid. The yield was 42%.

Spectral data of compound (IB-8): ¹H NMR (400 MHz, DMSO-d₆, 298K): δ 10.53 (s, br, 1H), 8.30 (s, 1H), 7.96 (s, 1H), 7.80 (s, br, 1H), 7.27 (s, br, 1H), 7.19 (s, br, 1H), 6.91 (s, 1H), 3.92 (s, 3H). ¹⁹F NMR (376 MHz, d₆-DMSO, 298K) δ −59.64 (s, 3F), −64.26 (s, 3F), −68.27 (s, 3F). MS (FAB, ¹⁹⁵Pt): observed (actual) m/z 702 (702) [M].

### Example 11

Preparation of Compound (IB-9):

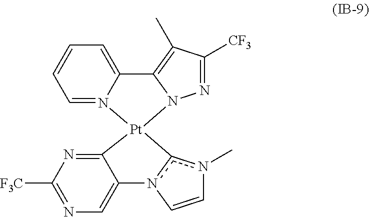

Except that the reactant (1-methyl-3-(2-tert-butylpyrimidin-5-yl)imidazol-2-ylidine) silver iodide was replaced with (1-methyl-3-(2-trifluoromethylpyrimidin-5-yl)imidazol-2-ylidine)silver iodide and the reactant 5-(1-methyl-1H-imidazol-2-yl)-3-(trifluoromethyl)-1H-pyrazole was replaced with 2-(4-methyl-3-(trifluoromethyl)-1H-pyrazol-5-yl)pyridine, the synthesis of compound (IB-9) followed the similar synthetic steps of compound (IA-1). Since the solubility of the product was poor, water was added to the reaction mixture and the mixture was filtered. The precipitate was washed with ether for several times. The crude product was dried under vacuum and sublimed at 270° C. to obtain an orange solid. The yield was 47%.

Spectral data of compound (IB-9): ¹H NMR (400 MHz, DMSO-d₆, 298K): 10.64 (d, J=5.4 Hz, 1H), 8.51 (s, 1H), 8.04 (t, J=7.8 Hz, 1H), 8.00 (d, J=1.7 Hz, 1H), 7.63 (d, J=7.8 Hz, 1H), 7.37 (d, J=1.7 Hz, 1H), 7.24 (t, J=5.4 Hz, 1H), 4.24 (s, 3H), 2.30 (s, 3H). ¹⁹F NMR (376 MHz, DMSO-d₆, 298K): δ −58.22 (s, 3F), −68.23 (s, 3F). MS (FAB, ¹⁹⁵Pt): observed (actual) m/z 648 (648) [M⁺].

### Example 12

Preparation of Compound (IB-10):

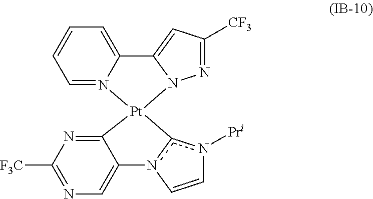

Except that the reactant (1-methyl-3-(2-tert-butylpyrimidin-5-yl)imidazol-2-ylidine)silver iodide was replaced with (1-isopropyl-3-(2-trifluoromethylpyrimidin-5-yl)imidazol-2-ylidine)silver iodide and the reactant 5-(1-methyl-1H-imidazol-2-yl)-3-(trifluoromethyl)-1H-pyrazole was replaced with 2-(3-(trifluoromethyl)-1H-pyrazol-5-yl)pyridine, the synthesis of compound (IB-10) followed the similar synthetic steps of compound (IA-1). After the reaction was completed, the solvent was removed and the residue was dissolved in dichloromethane. The organic layers were combined, washed with water, dried with anhydrous sodium sulfate, filtered and evaporated to dryness, and the residue was then purified with column chromatography (silicone, ethyl acetate:n-hexane=1:3) to obtain a yellow solid. The yield was 41%.

Spectral data of compound (IB-10): ¹H NMR (400 MHz, CDCl₃, 298K): δ 10.93 (d, J=5.6 Hz, 1H), 8.11 (s, 1H), 7.91 (td, J=7.6, 1.5 Hz, 1H), 7.61 (dd, J=7.6 Hz, 1H), 7.39 (d, J=2.0 Hz, 1H), 7.35 (dd, J=5.6, 1.5 Hz, 1H), 7.17 (d, J=2.0 Hz, 1H), 6.91 (septet, J=6.6 Hz, 1H), 6.78 (s, 1H), 1.51 (d, J=6.6 Hz, 6H). ¹⁹F NMR (400 MHz, CDCl₃, 298K): δ −61.01 (s, 3F), −69.59 (s, 3F). MS (FAB, ¹⁹⁵Pt): observed (actual) m/z 662 (662) [M⁺].

### Example 13

Preparation of Compound (IB-11):

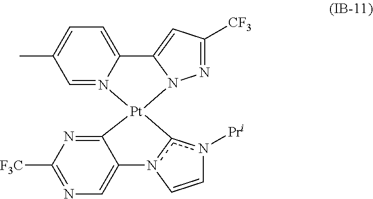

Except that the reactant (1-methyl-3-(2-tert-butylpyrimidin-5-yl)imidazol-2-ylidine) silver iodide was replaced with (1-isopropyl-3-(2-trifluoromethylpyrimidin-5-yl)imidazol-2-ylidine)silver iodide and the reactant 5-(1-methyl-1H-imidazol-2-yl)-3-(trifluoromethyl)-1H-pyrazole was replaced with 5-methyl-2-(3-(trifluoromethyl)-1H-pyrazol-5-yl)pyridine, the synthetic steps of compound (IB-11) were similar to the synthetic steps of compound (IA-1). After the reaction was completed, the solvent was removed and the residue was dissolved in dichloromethane. The organic layers were combined, washed with water, dried with anhydrous sodium sulfate, filtered and evaporated to dryness, and the residue was then purified with column chromatography (silicone, ethyl acetate:n-hexane=1:3) to obtain a yellow solid with a yield of 45%.

Spectral data of compound (IB-11): ¹H NMR (400 MHz, CDCl₃, 298K): δ 10.82 (s, 1H), 8.01 (s, 1H), 7.70 (d, J=7.0 Hz, 1H), 7.48 (d, J=7.0 Hz, 1H), 7.34 (d, J=1.9 Hz, 1H), 7.14 (d, J=1.9 Hz, 1H), 6.90 (septet, J=6.7 Hz, 1H), 6.71 (s, 1H), 2.45 (s, 3H), 1.48 (d, J=6.7 Hz, 6H). ¹⁹F NMR (376 MHz, CDCl₃, 298K): δ −60.89 (s, 3F), −69.49 (s, 3F). MS (FAB, ¹⁹⁵Pt): observed (actual) m/z 676 (676) [M⁺].

It should be mentioned that, a hydrogen bond exists between two chelating ligands of the platinum complex of the invention, such that the structure of the platinum complex of the invention is more stable. The formation of such hydrogen bond between the chelating ligands can be proved from X-ray crystal structure analysis. Specifically, the nitrogen atom and the hydrogen atom on the leftmost side of the structure shown in general formula (I-1) form an inter-ligand hydrogen bond, the non-bonding distance between the nitrogen atom and the hydrogen atom is reduced to the range of 2.2 Å to 2.5 Å, and the latter is shorter than the total length of van der Waals radii of nitrogen and hydrogen atoms. The formation of hydrogen bond can also be confirmed from the chemical shift of ¹H NMR spectrum. Specifically, when a nitrogen atom and a hydrogen atom form a hydrogen bond, the chemical shift of the hydrogen atom is shifted to a lower magnetic field region. In the platinum complex of the invention, after the nitrogen atom and the hydrogen atom on the leftmost side of the structure shown in general formula (I-1) form an inter-ligand hydrogen bond, the chemical shift of the hydrogen atom is shifted to a lower field regime in comparison to the case in which a hydrogen bond is not formed. For instance, the chemical shift of the hydrogen atom which forms the hydrogen bond with the nitrogen atom in each of the compounds synthesized in examples 1 to 5 is greater than δ=8.6 ppm, and the chemical shift of the hydrogen atom which forms the hydrogen bond with the nitrogen atom in each of the compounds synthesized in examples 6 to 13 is greater than δ=10.4 ppm. When a hydrogen bond is not formed, the chemical shift of the hydrogen atom is only at about δ=6 ppm and 8 ppm.

After the chelating ligand of the invention is coordinated to a platinum metal, the acidity of the adjacent C—H hydrogen atom on the chelating ligands can be increased, and the basicity of the adjacent nitrogen atom not bonded to the platinum metal can also be increased, and therefore the nitrogen atom can more readily form a hydrogen bond with the adjacent hydrogen atom.

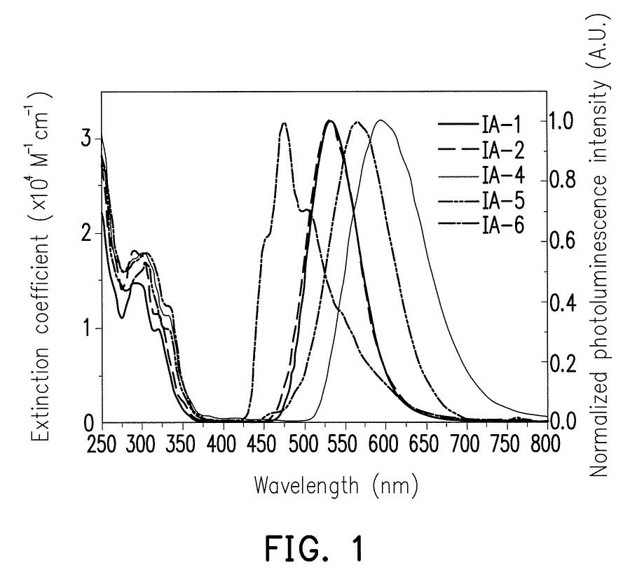

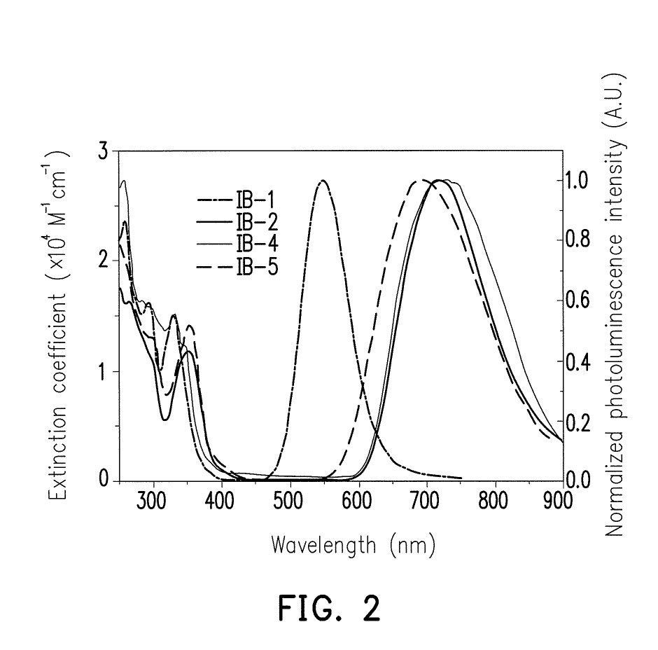

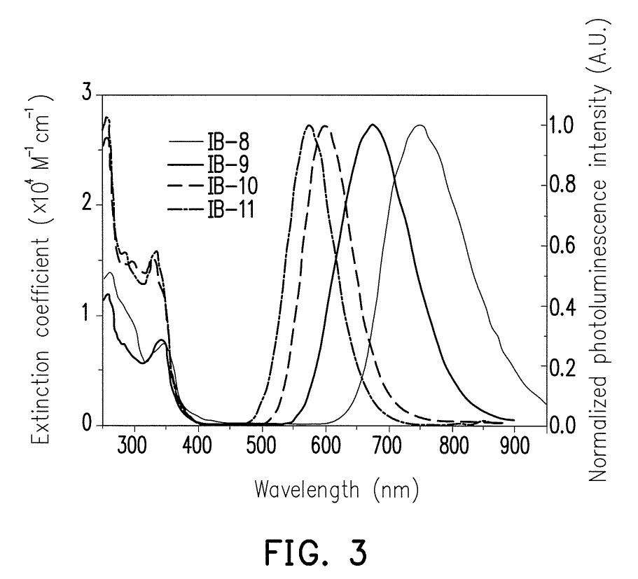

The absorption spectrum and emission spectrum of each of compounds (IA-1) to (IA-2), (IA-4) to (IA-6), and (I-B1) to (IB-2), (IB-4) to (IB-5), (IB-8) to (IB-11) synthesized in examples 1 to 13 are shown in FIG. 1 to FIG. 3, and the absorption peak position (abs λₘₐₓ), emission peak position (em λₘₐₓ), luminescent lifetime (τ), and quantum yield (Φ) are listed in Table 1 below.

TABLE 1

| | abs λₘₐₓ^{[a,b]}(nm) | em λₘₐₓ^{[c]} | τ^{[c]} | Φ^{[c]} |
|---|---|---|---|---|
| compound | (ε*10⁻⁴, M⁻¹ · cm⁻¹) | (nm) | (μs) | (%) |
| (IA-1) | 290 (1.46), 319 (0.99)^{[a]} | 540 | 1.29 | 81 |
| (IA-2) | 289 (1.83), 322 (1.33)^{[a]} | 532 | 1.89 | 68 |
| (IA-4) | 301 (1.79), 331 (1.24)^{[b]} | 595 | 1.55 | 82 |
| (IA-5) | 303 (1.69), 331 (1.13)^{[a]} | 567 | 1.85 | 85 |
| (IA-6) | 304 (1.80), 331 (1.24)^{[a]} | 451, 474, 529 | 8.07 | 56 |
| (IB-1) | 295 (1.61), 330 (1.49)^{[a]} | 549 | 1.04 | 100 |
| (IB-2) | 352 (1.17)^{[a]} | 721 | 0.22 | 100 |
| (IB-4) | 294 (1.61), 329 (1.48)^{[b]} | 726 | 1.10 | 57 |
| (IB-5) | 354 (1.41)^{[b]} | 669 | 0.87 | 100 |
| (IB-8) | 345 (0.77)^{[b]} | 750 | 0.56 | — |
| (IB-9) | 346 (0.73)^{[b]} | 675 | 0.94 | 70 |
| (IB-10) | 330 (1.50)^{[a]} | 602 | 1.37 | 100 |
| (IB-11) | 333 (1.60)^{[a]} | 570 | 1.63 | 90 |

^{[a]}UV light/visible light spectrum measured in CH₂Cl₂ solution (10⁻⁵M)
^{[b]}UV light/visible light spectrum measured in THF solution (10⁻⁵M)
^{[c]}Emission characteristics measured in powder state.

FIGS. 1 to 3 show the absorption spectrum and the emission spectrum of each of compounds (IA-1) to (IA-2), (IA-4) to (IA-6) and (I-B1) to (IB-2), (IB-4) to (IB-5), (IB-8) to (IB-11) synthesized in examples 1 to 13 of the invention. It can be known from FIGS. 1 to 3 and Table 1 that, the platinum complex of the invention has an emission wavelength of about 450 nm and 750 nm, so therefore the application thereof is relatively broad. For instance, when the emission wavelengths of the platinum complexes (IB-2), (IB-4), (IB-8) are greater than 700 nm and fall within the range of near-IR light, and such platinum complexes can be applied in the military or medical field. When the emission wavelengths of platinum complexes (IA-1) to (IA-2), (IA-4) to (IA-6), (IB-1), (IB-5), (IB-9) to (IB-11) of the invention are in the visible light range, such platinum complexes can be applied in the OLED field.

In the above embodiments, although the platinum complexes of general formulas (IA) and (IB) are used as examples, the invention is not limited thereto. Those having ordinary skill in the art should understand that, any platinum complex for which intramolecular hydrogen bond exists between two chelating ligands and at least one chelating ligand has a carbene fragment is within the scope of the invention.

Based on the above, a hydrogen bond exists between two chelating ligands of the platinum complex of the invention, and therefore the bonding strength of the chelating ligands and a central platinum metal can be increased, such that the structure of the platinum complex of the invention is more stable. The total negative charge of two chelating ligands of the platinum complex of the invention is the same as the positive charge of the central platinum metal ion, so a neutral platinum complex can be formed. A neutral complex generally has better volatility, and therefore a multilayer OLED light-emitting device can be formed using an evaporation method, and the luminous efficiency thereof can be improved. Moreover, the platinum complex of the invention has two N—Pt coordination bonds and two C—Pt coordination bonds. Since the bond energy of C—Pt is greater than the bond energy of N—Pt, by increasing the relative number of C—Pt bonds, the overall bonding strength between the chelating ligands and the central metal atom can be increased. Accordingly, the energy level of metal-centered dd excited states can be increased, such that influence on the lowest energy excited state from the dd excited states can be reduced, and non-radiative quenching can be reduced. As a result, the luminous efficiency of the complex can be increased. Moreover, in the platinum complex of the invention, the ring structures of A1 and A3 contain nitrogen atoms with high electronegativity, and such nitrogen atoms are beneficial to increase the stacking effect between molecules, reduce the Pt—Pt intermolecular distance, and induce metal-metal-to-ligand charge transfer transition (MMLCT) in the solid state. Therefore, shorter luminous half-life and better emission efficiency of the complex of the invention are provided.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A platinum complex having a structure represented by general formula (I): 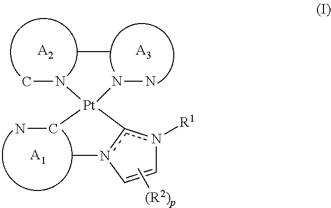
wherein
A1 to A3 are each independently a five-membered ring or a six-membered ring;
R¹ is substituted or unsubstituted C₁-C₁₂ alkyl or substituted or unsubstituted C₆-C₁₂ aryl;
each R² is independently hydrogen, substituted or unsubstituted C₁-C₁₂ alkyl, or substituted or unsubstituted C₁-C₆ alkoxy;
p is an integer of 1 to 2;
when p is equal to 2, two R²'s can be joined to form a C₃-C₈ aromatic ring; and
a first chelating ligand having A1 and a carbene fragment has a minus one formal charge and a second chelating ligand having both A2 and A3 has a minus one formal charge.

2. The platinum complex of claim 1, having a structure represented by general formula (I-1): 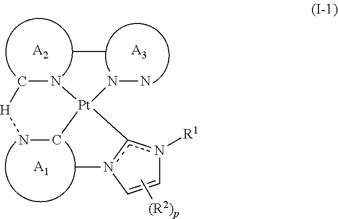
wherein a hydrogen bond exists between the first chelating ligand and the second chelating ligand.

3. The platinum complex of claim 1, having a structure represented by general formula (IA): 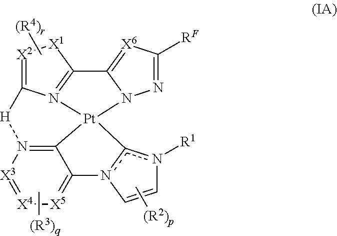
wherein
X¹ is carbon, oxygen, sulfur, or nitrogen;
X² to X⁶ are each independently carbon or nitrogen;
R^{F} is an electron withdrawing group;
R¹ is substituted or unsubstituted C₁-C₁₂ alkyl or substituted or unsubstituted C₆-C₁₂ aryl;
each R² is independently hydrogen, substituted or unsubstituted C₁-C₁₂ alkyl, or substituted or unsubstituted C₁-C₆ alkoxy;
p is an integer of 1 to 2;
each R³ is independently hydrogen, substituted or unsubstituted C₁-C₁₂ alkyl, or substituted or unsubstituted C₁-C₆ alkoxy or —CₘF₂ₘ₊₁, m is an integer of 0 to 3;
q is an integer of 0 to 3;
each R⁴ is independently hydrogen, fluorine, substituted or unsubstituted C₁-C₁₂ alkyl, substituted or unsubstituted C₆-C₁₂ aryl, or substituted or unsubstituted C₁-C₆ alkoxy;
r is an integer of 0 to 2;
when p is equal to 2, two R²'s can be joined to form a C₃-C₈ aromatic ring;
when q is equal to or greater than 2, two or more R³'s can be joined to form a C₃-C₈ aromatic ring; and
when r is equal to 2, two R⁴'s can be joined to form a C₃-C₈ aromatic ring.

4. The platinum complex of claim 3, wherein R^{F} comprises —CₘF₂ₘ₊₁ and m is an integer of 0 to 3.

5. The platinum complex of claim 3, having a structure represented by one of formula (IA-1) to formula (IA-8):

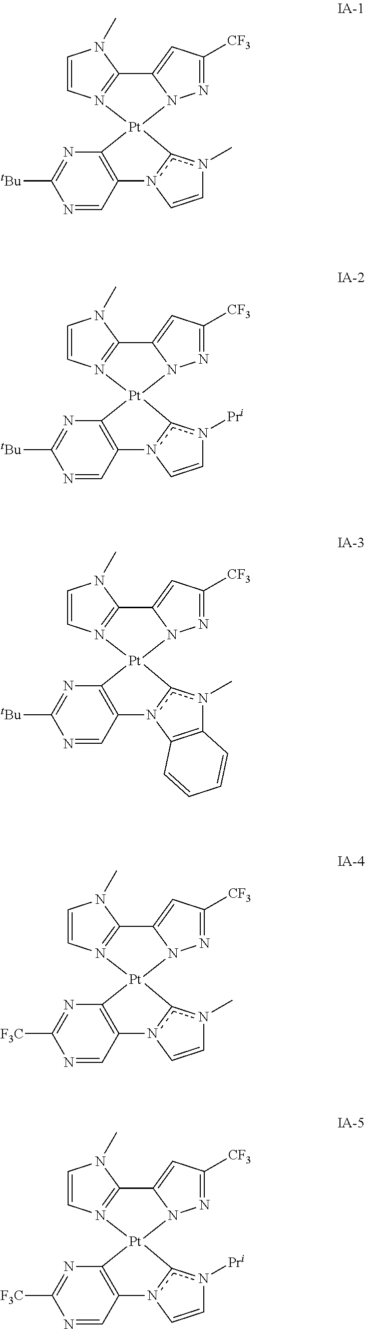

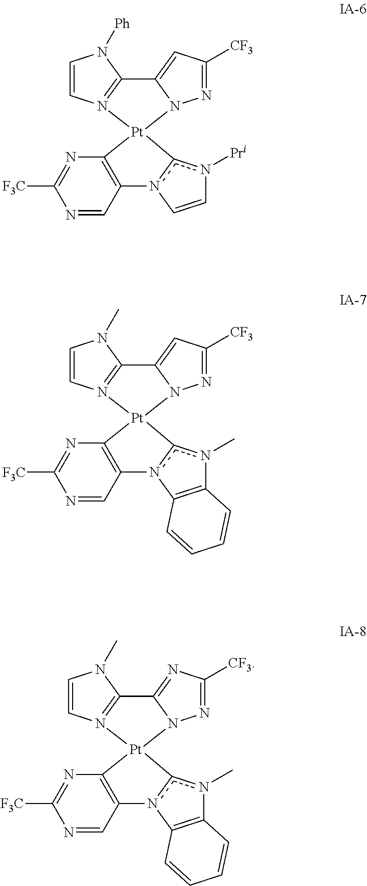

6. The platinum complex of claim 1, having a structure represented by general formula (IB): 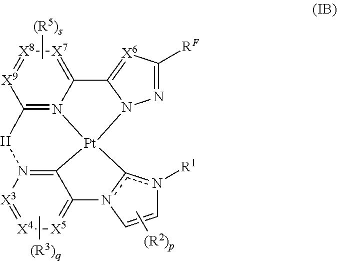
wherein
X³ to X⁹ are each independently carbon or nitrogen;
R^{F} is an electron withdrawing group;
R¹ is substituted or unsubstituted C₁-C₁₂ alkyl or substituted or unsubstituted C₆-C₁₂ aryl;
each R² is independently hydrogen, substituted or unsubstituted C₁-C₁₂ alkyl, or substituted or unsubstituted C₁-C₆ alkoxy;
p is an integer of 1 to 2;
each R³ is independently hydrogen, substituted or unsubstituted C₁-C₁₂ alkyl, or substituted or unsubstituted C₁-C₆ alkoxy or —CₘF₂ₘ₊₁, m is an integer of 0 to 3;
q is an integer of 0 to 3;
each R⁵ is independently hydrogen, fluorine, substituted or unsubstituted C₁-C₁₂ alkyl, or substituted or unsubstituted C₁-C₆ alkoxy;
s is an integer of 0 to 3;
when p is equal to 2, two R²'s can be joined to form a C₃-C₈ aromatic ring;
when q is equal to or greater than 2, two or more R³'s can be joined to form a C₃-C₈ aromatic ring; and
when s is equal to or greater than 2, two or more R⁵'s can be joined to form a C₃-C₈ aromatic ring.

7. The platinum complex of claim 6, having a structure represented by one of formula (IB-1) to formula (IB-15):

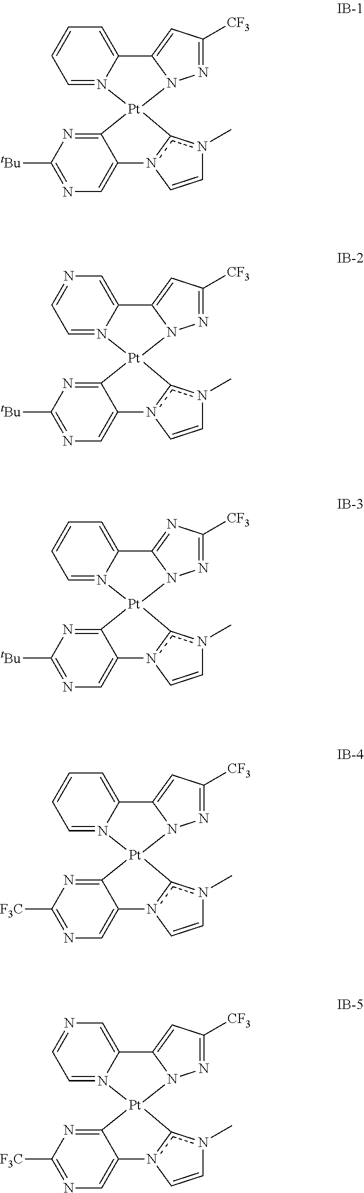

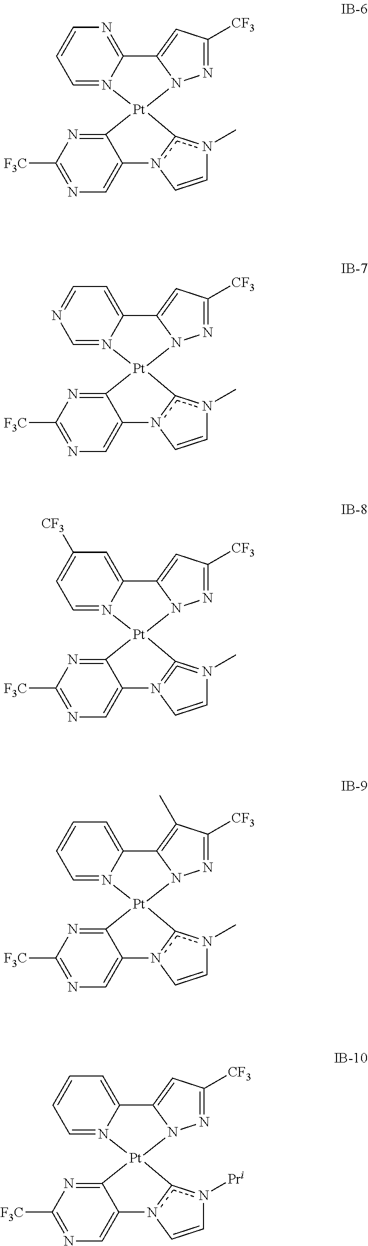

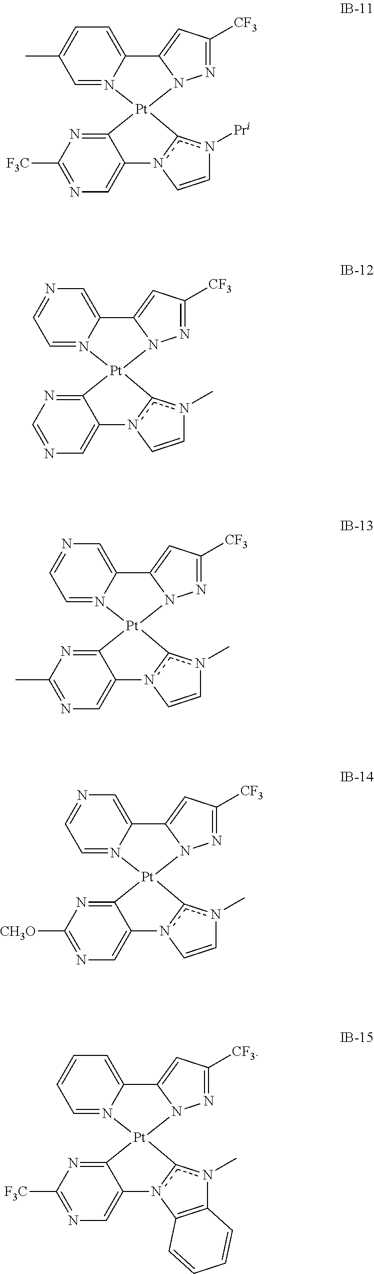

8. The platinum complex of claim 1, wherein an emission wavelength thereof is between 450 nm and 750 nm.

9. An apparatus emitting visible light or near-infrared light, comprising the platinum complex of claim 1.

10. An organic light-emitting diode, comprising two electrodes and a light-emitting layer disposed between the two electrodes, wherein the light-emitting layer contains the platinum complex of claim 1.
